(19) United States
(12) Patent Application Publication
(10) Pub. No.: US 2026/0240011 A1
(43) Pub. Date: Aug. 13, 2026

(54) SEMICONDUCTOR DEVICE AND METHOD OF MANUFACTURING SEMICONDUCTOR DEVICE

(71) Applicant: Taiwan Semiconductor Manufacturing Company, Ltd., Hsinchu (TW)

(72) Inventors: Chia-En HUANG, Hsinchu (TW); Tzu-Chieh CHEN, Hsinchu (TW)

(73) Assignee: Taiwan Semiconductor Manufacturing Company, Ltd., Hsinchu (TW)

(21) Appl. No.: 19/048,029

(22) Filed: Feb. 7, 2025

(51) Int. Cl. H01L 23/538; H01L 25/07

(52) U.S. Cl. CPC H10W 70/65; H10W 70/611; H10W 90/00; H10W 72/01

(57) ABSTRACT

A semiconductor device embodiment includes a first semiconductor die including a first power distribution network, a second semiconductor die over the first semiconductor die and including a second power distribution network, a first set of conductive paths through the first semiconductor die and the second semiconductor die and associated with a first power net group, and a second set of conductive paths through the first semiconductor die and the second semiconductor die and associated with a second power net group. The semiconductor device further includes one or more power management controllers configured to set the first power distribution network as electrically coupled to the first set of conductive paths, the second set of conductive paths, or both; or to set the second power distribution network as electrically coupled to the first set of conductive paths, the second set of conductive paths, or both.

### BACKGROUND

Modern integrated circuit (IC) manufacturing technology enables faster, smaller, and more efficient devices. In some examples, the sizes of electrical components and transistors have shrunk to include more components in an individual semiconductor die, or even more layers of components in a semiconductor die. In some examples, multiple semiconductor dies are mounted side-by-side on a package substrate or an interposer in an IC package, or multiple dies are stacked one over another in an IC package or on a printed circuit board (PCB) substrate. These advances in IC manufacturing technology have supported the development of a wide variety of digital devices, such as a memory device or a system-in-package (SiP) device incorporating, e.g., at least a processing device and a memory device.

In some applications, a memory device includes one or more semiconductor dies based on various configurations. In some examples, a memory device is based on multiple memory dies stacked one over another within an IC package to enable high-density storage while minimizing the footprint. In some examples, a memory device is based on a back-end-of-line (BEOL) memory configuration integrating memory cells and the corresponding driving and sensing circuitry in the same die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a portion of a memory die, in accordance with some embodiments.

FIG. 2A is a simplified cross-sectional view of a first semiconductor device example, in accordance with some embodiments.

FIG. 2B is a simplified functional block diagram of the first semiconductor device example in FIG. 2A, in accordance with some embodiments.

FIGS. 3A-3B are block diagrams of a power management controller and a plurality of switches of a power distribution network, in accordance with some embodiments.

FIG. 4 is a simplified cross-sectional view of a second semiconductor device example, in accordance with some embodiments.

FIGS. 5A-5C are simplified cross-sectional views of a third semiconductor device example, a fourth semiconductor device example, and a fifth semiconductor device example, in accordance with some embodiments.

FIGS. 6A-6B are simplified cross-sectional views of a sixth semiconductor device example and a seventh semiconductor device example, in accordance with some embodiments.

FIG. 7 is a simplified cross-sectional view of an eighth semiconductor device example, in accordance with some embodiments.

FIG. 8 is a simplified cross-sectional view of a ninth semiconductor device example, in accordance with some embodiments.

FIG. 9 is a simplified cross-sectional view of a tenth semiconductor device example, in accordance with some embodiments.

FIG. 10 is a simplified cross-sectional view of an eleventh semiconductor device example, in accordance with some embodiments.

FIG. 11 is a flowchart of a method of manufacturing a semiconductor device, in accordance with some embodiments.

FIG. 12 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

In some applications with multiple semiconductor dies stacked one over another, different dies may operate based on different power domains or have different requirements or limitations to the supply voltages. Based on one or more embodiments of the present disclosure, multiple power net groups are made available to various semiconductor dies in the stack. In some embodiments, each power net group corresponds to a group of power nets (e.g., connection points or paths) that are configured to carry supply voltages or a ground voltage. In some embodiments, a power distribution network of a semiconductor die may be selectively coupled to one or more of the power net groups. In some embodiments, power distribution networks of different semiconductor dies may be selectively coupled to the same power net group. Accordingly, based on one or more embodiments of the present disclosure, the power distribution networks of various semiconductor dies may be selectively energized by one or more power net groups based on the operation modes, loads, noise levels, and/or operation frequencies of various circuit blocks of the semiconductor dies. Also, different power distribution networks of various semiconductor dies may be electrically coupled together or isolated to further noise cancellation or noise separation.

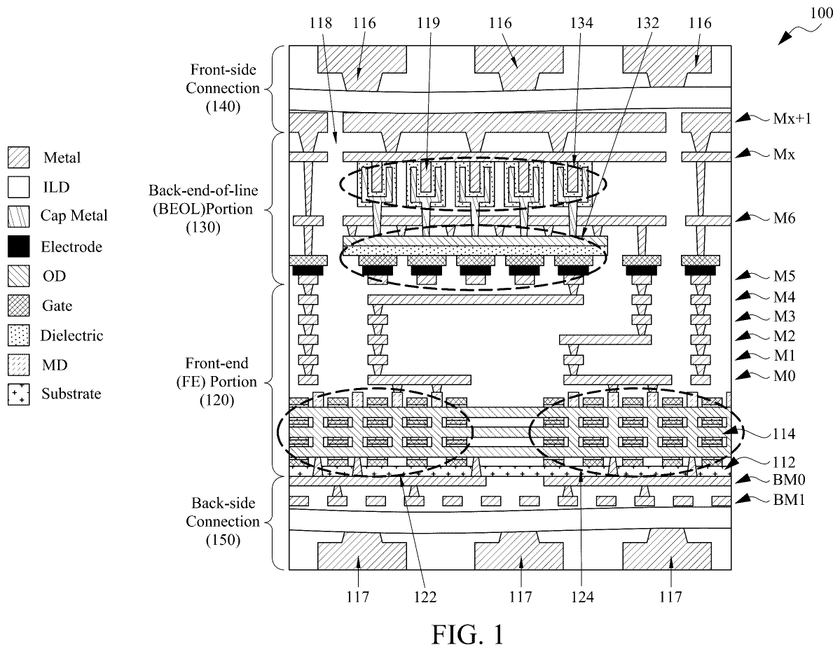

FIG. 1 is a cross-sectional view of a portion of a memory die 100, in accordance with some embodiments. In some embodiments, an integrated circuit (IC) device includes a plurality of semiconductor dies stacked one over another, and memory die 100 in FIG. 1 is illustrated as a non-limiting example of one of the stacked semiconductor dies. In some embodiments, the stacked semiconductor dies correspond to a memory die (e.g., based on memory die 100), a processor die, a power management die, a communication die, an input/output interface die, a combination thereof, or the like. In some embodiments, the cross-sectional view in FIG. 1 is a simplified cross-sectional view, with many features simplified or not depicted.

In some embodiments, memory die 100 includes a memory cell array and control circuitry configured to control an operation of the memory cell array. In some embodiments, memory die 100 further includes a plurality of word lines electrically coupled to corresponding rows of memory cells of the memory cell array, and a plurality of bit lines electrically coupled to corresponding columns of memory cells of the memory cell array. Each one of the memory cells in the memory cell array is coupled to the control circuitry by at least one of the word lines and at least one of the bit lines. In some embodiments, each one of the memory cells in the memory cell array is electrically coupled to the control circuitry by two word lines, including a read word line for read operations and a write word line for write operations. In some embodiments, each one of the memory cells in the memory cell array is electrically coupled to the control circuitry by a single word line that is usable for read operations and/or for write operations. Moreover, in some embodiments, each one of the memory cells in the memory cell array is further electrically coupled to the control circuitry by a single bit line or a pair of differential bit lines. Various numbers of word lines, bit lines, and/or other types of signal lines of the memory die 100 are within the scope of various embodiments.

In some embodiments, the control circuitry of memory die 100 includes a row decoder, a plurality of word line drivers, a column decoder, and a plurality of sense amplifiers and/or bit line drivers. In some embodiments, the row decoder interprets at least a portion of an address of a memory cell to be accessed during a read operation or a write operation, and selects one of the word line drivers to activate one of the word lines that corresponds to the address. In some embodiments, the selected one of the word line drivers activates a specific row (e.g., the corresponding word line) to enable the access of the memory cells in the row. In some embodiments, the column decoder interprets at least another portion of the address and selects one of the sense amplifiers and/or bit line drivers coupled to one of the bit lines that corresponds to the address. In some embodiments, the selected one of the sense amplifiers and/or bit line drivers is configured to read the binary value stored in the memory cell specified by the decoded row and column via the corresponding bit line. In some embodiments, the selected one of the sense amplifiers and/or bit line drivers is configured to write the binary value to be stored in the memory cell specified by the decoded row and column via the corresponding bit line.

In FIG. 1, memory die 100 includes a substrate 112 (corresponding to “Substrate” in the legend), oxide diffusion (OD) layers 114 (corresponding to “OD” in the legend) over substrate 112, a plurality of metal-to-drain/source (MD) structures (corresponding to “MD” in the legend), a first set of gate dielectric structures (corresponding to “Dielectric” in the legend) adjacent to OD layers 114, and a first set of gate structures (corresponding to “Gate” in the legend) surrounding the corresponding ones of the first set of gate dielectric structures. Memory die 100 includes a plurality of front-side metallization layers (e.g., M0, M1, M2, M3, M4, M5, M6, Mx, and Mx+1 layers, corresponding to “Metal” in the legend) and the corresponding via layers (not labeled, also corresponding to “Metal” in the legend) stacked one over another over the MD structures and/or the set of the gate structures. Memory die 100 also includes a plurality of back-side metallization layers (e.g., BM0 and BM1 layers, corresponding to “Metal” in the legend) and the corresponding via layers (not labeled, also corresponding to “Metal” in the legend) stacked one over another under substrate 112.

In some embodiments, memory die 100 includes one or more front-side redistribution layers (not in FIG. 1) over the plurality of front-side metallization layers. In some embodiments, memory die 100 includes conductive terminal structures (e.g., conductive bumps, copper pillar bumps, solder bumps, or the like, not in FIG. 1) over the front-side conductive pad structures 116. In some embodiments, memory die 100 includes one or more back-side redistribution layers (not in FIG. 1) under the plurality of back-side metallization layers and includes back-side conductive pad structures 117 under the one or more back-side redistribution layers. In some embodiments, memory die 100 further includes conductive terminal structures (e.g., conductive bumps, copper pillar bumps, solder bumps, or the like, not in FIG. 1) under the back-side conductive pad structures 117. Moreover, memory die 100 includes a plurality of interlayer dielectric (ILD) layers (collectively labeled as “118” and corresponding to “ILD” in the legend) surrounding and between at least the plurality of front-side metallization layers, front-side conductive pad structures 116, the plurality of back-side metallization layers, and back-side conductive pad structures 117.

In some embodiments, substrate 112 includes silicon, gallium arsenide, indium phosphide, silicon germanium, a combination thereof, or the like. In some embodiments, substrate 112 further includes one or more insulation layers. In some embodiments, OD layer 114 includes doped semiconductor materials suitable for forming channel structures of transistors. In some embodiments, the first set of gate structures includes tantalum nitride, titanium nitride, tungsten, aluminum, polysilicon, a combination thereof, or the like. In some embodiments, the first set of gate dielectric structures includes silicon dioxide. In some embodiments, the metallization layers and the corresponding via layers include a conductive material including copper, aluminum, gold, tungsten, a combination thereof, or the like. In some embodiments, ILD layers 118 include silicon dioxide.

In FIG. 1, as a non-limiting example, memory die 100 further includes a set of gate electrode structures (corresponding to “Electrode” in the legend) over M5 layer, a second set of gate structures (corresponding to “Gate” in the legend) over the set of gate electrode structures, a second set of gate dielectric structures (corresponding to “Dielectric” in the legend) over the second set of gate structures, and a set of OD structures (corresponding to “OD” in the legend) over the second set of gate dielectric structures. In FIG. 1, as a non-limiting example, memory die 100 further includes a set of capacitor metal structures (corresponding to “Cap Metal” in the legend) over the M6 layer and extending toward the Mx layer, a set of capacitor terminal structures (e.g., the structure 119, corresponding to “Metal” in the legend) extending from the Mx layer toward the M6 layer, and capacitor dielectric structures (also corresponding to “Dielectric” in the legend) between the set of capacitor metal structures and the set of capacitor terminal structures.

In some embodiments, the set of OD structures includes indium gallium zinc oxide, zinc oxide, indium oxide, tin dioxide, a combination thereof, or the like, for forming N-type channels. In some embodiments, the set of OD structures includes nickel oxide, cuprous oxide, copper aluminum oxide, copper gallium oxide, copper indium oxide, strontium copper oxide, tin oxide, a combination thereof, or the like, for forming P-type channels. In some embodiments, the second set of gate structures includes tantalum nitride, titanium nitride, tungsten, aluminum, polysilicon, a combination thereof, or the like. In some embodiments, the second set of gate dielectric structures includes hafnium oxide, silicon dioxide, aluminum oxide, silicon oxynitride, a combination thereof, or the like. In some embodiments, the set of capacitor metal structures includes tantalum nitride, titanium nitride, tungsten, aluminum, polysilicon, ruthenium, cobalt, copper, a combination thereof, or the like.

In FIG. 1, memory die 100 is a non-limiting example of a semiconductor die that includes a front-end (FE) portion 120, a back-end-of-line (BEOL) portion 130, a front-side connection 140, and a back-side connection 150. In this example, FE portion 120 includes substrate 112, components formed on or partially embedded in substrate 112, and a first portion of front-side metallization layers (e.g., M0-M4 layers). In some embodiments, FE portion 120 further includes a front-end-of-line (FEOL) portion and a middle-end-of-line (MEOL) portion of a semiconductor die. In some embodiments, BEOL portion 130 includes a second portion of front-side metallization layers (e.g., M5-Mx layers) and components formed within the second portion of front-side metallization layers. In some embodiments, front-side connection 140 includes a third portion of front-side metallization layers (e.g., Mx+1 layer), front-side conductive pad structures 116, and the one or more front-side redistribution layers. In some embodiments, back-side connection 150 includes the back-side metallization layers (e.g., BM0 and BM1 layers), back-side conductive pad structures 117, and the one or more back-side redistribution layers.

In FIG. 1, FE portion 120 of memory die 100 includes transistors formed based on OD layers 114, MD structures, the first set of gate dielectric structures, and the first set of gate structures, which are further configured to implement one or more word line drivers (e.g., a word line driver 122), one or more sense amplifiers (e.g., a sense amplifier 124), and/or other circuitry. In FIG. 1, BEOL portion 130 of memory die 100 includes transistors 132 formed based on the set of gate electrode structures over the M5 layer, the second set of gate structures, the second set of gate dielectric structures, and the set of OD structures. In some embodiments, BEOL portion 130 of memory die 100 further includes capacitors 134 formed based on the set of capacitor metal structures over the M6 layer, the set of capacitor terminal structures from the Mx layer, and the capacitor dielectric structures.

In some embodiments, memory die 100 corresponds to a configuration having BEOL memory cells that are one-transistor, one-capacitor (1T1C) memory cells. In this example, transistors 132 and capacitors 134 constitute a memory cell array of 1T1C memory cells. In this example, word line driver 122 is electrically coupled to a word line (e.g., at the M5 layer) of a row of the memory cell array through the M0-M4 layers, and sense amplifier 124 is electrically coupled to a bit line (e.g., at the M6 layer) of a column of the memory cell array through the M0-M5 layers.

Memory die 100 in FIG. 1 corresponds to a configuration including control circuitry in the FE portion 120 and a memory cell array in BEOL portion 130. In some applications, memory die 100 is also referred to as having a circuit under array (CuA) configuration with 1T1C memory cells. In some embodiments, the memory cells in BEOL portion 130 correspond to magnetic tunnel junction memory cells, which include materials including iron mixed with cobalt, boron, nickel, magnesium oxide, a combination thereof, or the like. In some other embodiments, the memory cells in BEOL portion 130 correspond to volatile memory cells including dynamic random access memory (DRAM) cells or static random access memory (SRAM) cells, or non-volatile memory cells including floating-gate memory cells, ferroelectric random access memory (FRAM) cells, magnetic random access memory (MRAM) cells, phase-change memory (PCM) cells, or resistive random access memory (RRAM) cells.

Memory die 100 in FIG. 1 is a non-limiting example of a semiconductor die. In some embodiments, a semiconductor die in this disclosure includes portions corresponding to FE portion 120, BEOL portion 130, and front-side connection 140, and is free of having a portion corresponding to back-side connection 150. In some embodiments, a semiconductor die in this disclosure includes a portion corresponding to BEOL portion 130 that is free of having transistors or capacitors therein.

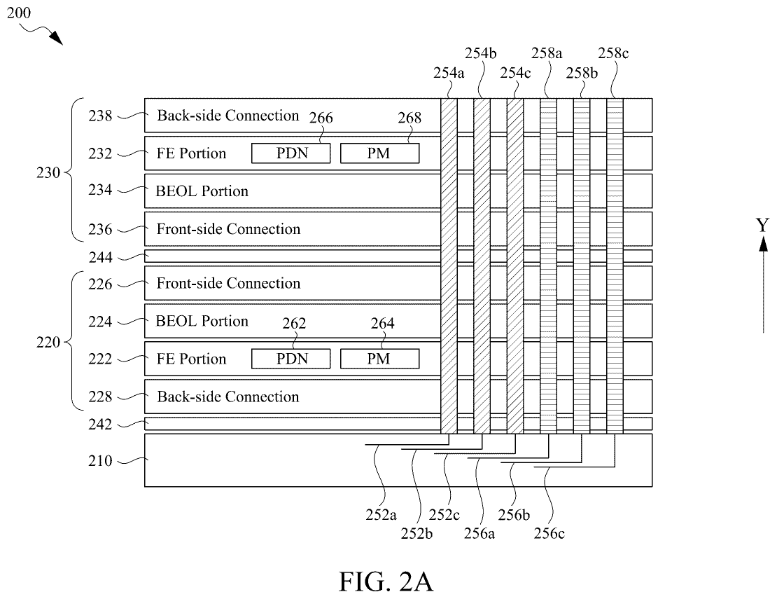

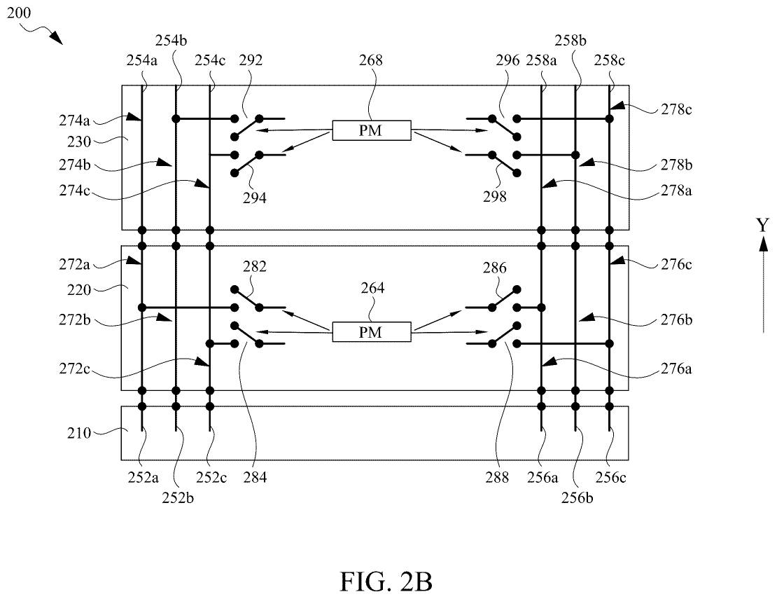

FIG. 2A is a simplified cross-sectional view of a first semiconductor device example 200, in accordance with some embodiments. In some embodiments, many features of first semiconductor device example 200 are simplified or not depicted in FIG. 2A.

In FIG. 2A, first semiconductor device example 200 includes a substrate 210, a first semiconductor die 220, and a second semiconductor die 230. In some embodiments, substrate 210 corresponds to a package substrate or an interposer in an IC package, or a printed circuit board (PCB) substrate. In this non-limiting example, first semiconductor die 220 includes an FE portion 222, a BEOL portion 224, a front-side connection 226, and a back-side connection 228 corresponding to FE portion 120, BEOL portion 130, front-side connection 140, and back-side connection 150 in FIG. 1. In this non-limiting example, second semiconductor die 230 also includes an FE portion 232, a BEOL portion 234, a front-side connection 236, and a back-side connection 238 corresponding to FE portion 120, BEOL portion 130, front-side connection 140, and back-side connection 150 in FIG. 1.

In FIG. 2A, first semiconductor die 220 is over substrate 210 along a stacking direction (e.g., the Y direction), with connection terminals of back-side connection 228 of first semiconductor die 220 electrically coupled to connection terminals of substrate 210 (e.g., the connections are represented by block 242). Also, in FIG. 2A, second semiconductor die 230 is over first semiconductor die 220 along the stacking direction, with connection terminals of front-side connection 226 of first semiconductor die 220 electrically coupled to connection terminals of front-side connection 236 of second semiconductor die 230 (e.g., the connections are represented by block 244). In some other embodiments, another substrate or one or more other semiconductor dies (not shown) are over second semiconductor die 230 and electrically coupled to connection terminals of back-side connection 238 of second semiconductor die 230. In some other embodiments, second semiconductor die 230 is free from having back-side connection 238.

In some embodiments, the orientation of first semiconductor die 220 and second semiconductor die 230 presented in FIG. 2A are a non-limiting example. In some other embodiments, since first semiconductor die 220 and second semiconductor die 230 include corresponding front-side and back-side connections, first semiconductor die 220, second semiconductor die 230, or both, are disposed in an upside down position compared to the example in FIG. 2A.

In FIG. 2A, first semiconductor device example 200 includes a first power net group and a second power net group. In some embodiments, the first power net group includes a first plurality of power nets configured to carry first supply voltages, and the second power net group includes a second plurality of power nets configured to carry second supply voltages. In FIG. 2A, first power net group includes three power lines 252a, 252b, and 252c in substrate 210 corresponding to different power nets thereof, and three sets of conductive paths 254a, 254b, and 254c through first semiconductor die 220 and second semiconductor die 230. In FIG. 2A, second power net group includes three power lines 256a, 256b, and 256c corresponding to different power nets thereof, in substrate 210 and three sets of conductive paths 258a, 258b, and 258c through first semiconductor die 220 and second semiconductor die 230. In some embodiments, each set of the sets of conductive paths 254a, 254b, 254c, 258a, 258b, and 258c is formed by conductive structures including metallization structures (e.g., via structures and/or conductive lines in metallization layers of a semiconductor die), through substrate via structures, connection terminals (e.g., micro bumps, copper pillar bumps, solder bumps, or the like), conductive paths, a combination thereof, or the like. In FIG. 2A, each set of the sets of conductive paths 254a, 254b, 254c, 258a, 258b, and 258c is a straight conductive path along the stacking direction. In some embodiments, the physical conductive structures of any of the sets of conductive paths 254a, 254b, 254c, 258a, 258b, and 258c are aligned along the stacking direction or misaligned along the stacking direction.

In some embodiments, power line 252a and the set of conductive paths 254a are electrically coupled together and configured to carry a first supply voltage of the first supply voltages; power line 252b and the set of conductive paths 254b are electrically coupled together and configured to carry a second supply voltage of the first supply voltages; and power line 252c and the set of conductive paths 254c are electrically coupled together and configured to carry a third supply voltage of the first supply voltages. Also, in some embodiments, power line 256a and the set of conductive paths 258a are electrically coupled together and configured to carry a first supply voltage of the second supply voltages; power line 256b and the set of conductive paths 258b are electrically coupled together and configured to carry a second supply voltage of the second supply voltages; and power line 256c and the set of conductive paths 258c are electrically coupled together and configured to carry a third supply voltage of the second supply voltages. In some embodiments, each one of the first supply voltages and the second supply voltages include a ground voltage, one or more positive supply voltages, one or more negative supply voltages, a combination thereof, or the like. In some embodiments, a subset of the first power net group and the second power net group correspond to a same nominal voltage level.

In FIG. 2A, first semiconductor die 220 includes a first power distribution network 262 (labeled “PDN”) configured to distribute supply voltages to various electrical components of first semiconductor die 220. In some embodiments, first power distribution network 262 includes conductive structures and/or electrical components in FE portion 222, BEOL portion 224, front-side connection 226, and/or back-side connection 226. First semiconductor die 220 further includes a first power management controller 264 (labeled “PM”). In some embodiments, first power management controller 264 is in FE portion 222 as depicted in FIG. 2A or in BEOL portion 224.

In FIG. 2A, second semiconductor die 230 includes a second power distribution network 266 (labeled “PDN”) configured to distribute supply voltages to various electrical components of second semiconductor die 230. In some embodiments, second power distribution network 266 includes conductive structures and/or electrical components in FE portion 232, BEOL portion 234, front-side connection 236, and/or back-side connection 236. Second semiconductor die 230 further includes a second power management controller 268 (labeled “PM”). In some embodiments, second power management controller 268 is in FE portion 232 as depicted in FIG. 2A or in BEOL portion 234.

In some embodiments, first semiconductor device example 200 includes one or more power management controllers. That is, in some embodiments, one of first power management controller 264 and second power management controller 268 is not included in first semiconductor device example 200. In some embodiments, both of first power management controller 264 and second power management controller 268 are included in first semiconductor device example 200.

In some embodiments, the one or more power management controllers (e.g., first power management controller 264 and/or second power management controller 268) are configured to set first power distribution network 262 as electrically coupled to at least one of the sets of conductive paths 254a, 254b, and 254c, at least one of the sets of conductive paths 258a, 258b, and 258c, or both. In some embodiments, the one or more power management controllers (e.g., first power management controller 264 and/or second power management controller 268) are configured to set second power distribution network 266 as electrically coupled to at least one of the sets of conductive paths 254a, 254b, and 254c, at least one of the sets of conductive paths 258a, 258b, and 258c, or both.

Accordingly, first power distribution network 262 of first semiconductor die 220 is configured to be selectively energized based on the first power net group, the second power net group, or a combination of the first power net group and the second power net group. Also, second power distribution network 266 of second semiconductor die 230 is configured to be selectively energized based on the first power net group, the second power net group, or a combination of the first power net group and the second power net group. In some embodiments, the one or more power management controllers (e.g., first power management controller 264 and/or second power management controller 268) of first semiconductor device example 200 are usable to selectively energize the first semiconductor die 220 and/or second semiconductor die 230 depending on the operation modes, loads, noise levels, and/or operation frequencies of various circuit blocks of the semiconductor dies.

FIG. 2B is a simplified functional block diagram of the first semiconductor device example 200 in FIG. 2A, in accordance with some embodiments. Components in FIG. 2B that are the same as the components in FIG. 2A are given the same reference numbers, and description thereof is simplified or omitted.

In FIG. 2B, as a non-limiting example, the sets of conductive paths 254a, 254b, and 254c includes conductive paths 272a, 272b, and 272c in first semiconductor die 220 and conductive paths 274a, 274b, and 274c in second semiconductor die 230. Also, as a non-limiting example, the sets of conductive paths 258a, 258b, and 258c include conductive paths 276a, 276b, and 276c in first semiconductor die 220 and conductive paths 278a, 278b, and 278c in second semiconductor die 230. In this example, conductive paths 272a, 272b, and 272c are electrically coupled to conductive paths 274a, 274b, and 274c and power lines 252a, 252b, and 252c, and are configured to carry the first supply voltages; and conductive paths 276a, 276b, and 276c are electrically coupled to conductive paths 278a, 278b, and 278c and power lines 256a, 256b, and 256c, and are configured to carry the second supply voltages.

In FIG. 2B, a first power distribution network (e.g., first power distribution network 262 in FIG. 2A) includes switches 282, 284, 286, and 288. In this example, switch 282 is configured to electrically couple the first power distribution network to conductive path 272a or electrically decouple the first power distribution network from conductive path 272a; switch 284 is configured to electrically couple the first power distribution network to conductive path 272c or electrically decouple the first power distribution network from conductive path 272c; switch 286 is configured to electrically couple the first power distribution network to conductive path 276a or electrically decouple the first power distribution network from conductive path 276a; and switch 288 is configured to electrically couple the first power distribution network to conductive path 276c or electrically decouple the first power distribution network from conductive path 276c. In some embodiments, a subset of switches 282, 284, 286, and 288 correspond to a same power node of the first power distribution network. In some embodiments, another subset of switches 282, 284, 286, and 288 correspond to different power nodes of the first power distribution network.

Also, in this example, a second power distribution network (e.g., second power distribution network 266 in FIG. 2A) includes switches 292, 294, 296, and 298. In this example, switch 292 is configured to electrically couple the second power distribution network to conductive path 274b or electrically decouple the second power distribution network from conductive path 274b; switch 294 is configured to electrically couple the second power distribution network to conductive path 274c or electrically decouple the second power distribution network from conductive path 274c; switch 296 is configured to electrically couple the second power distribution network to conductive path 278a or electrically decouple the second power distribution network from conductive path 278a; and switch 298 is configured to electrically couple the second power distribution network to conductive path 278c or electrically decouple the second power distribution network from conductive path 278c. In some embodiments, a subset of switches 292, 294, 296, and 298 correspond to a same power node of the second power distribution network. In some embodiments, another subset of switches 292, 294, 296, and 298 correspond to different power nodes of the second power distribution network.

In some embodiments, one or more power management controllers (e.g., power management controller 264 and/or power management controller 268) are configured to control the switches 282, 284, 286, 288, 292, 294, 296, and/or 298. For example, power management controller 264 is configured to control switches 282, 284, 286, and 288; and power management controller 268 is configured to control switches 292, 294, 296, and 298. In some embodiments, the one or more power management controllers are individually or collectively included in first semiconductor die 220, included in second semiconductor die 230, or included in a third semiconductor die different the first semiconductor die 220 and second semiconductor die 230.

In some embodiments, a power distribution network of a semiconductor die is selectively coupled to various power net groups based on the voltage levels and/or current capacity provided by the supply voltage power net groups, such that the power distribution network is energized by suitable supply voltages. In some embodiments, a power distribution network of a semiconductor die is selectively coupled to multiple power net groups in order to cancel power noise or stabilize voltage levels of the supply voltages provided to the power distribution network. In some embodiments, the power distribution networks of different semiconductor dies are selectively coupled to the same or different power net groups further based on the sleep/low power modes, loads, noise levels, and/or operation frequencies of the circuits energized by the corresponding power distribution networks, such that one power distribution network of one semiconductor die is electrically isolated from power noise on another power distribution network of another semiconductor die.

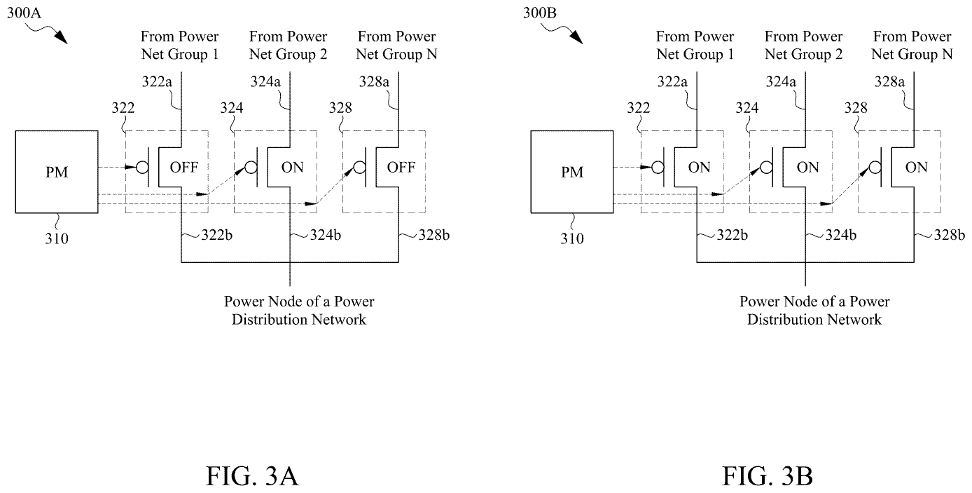

FIGS. 3A-3B are block diagrams 300A and 300B of a power management controller 310 in conjunction with a first switch 322, a second switch 324, and a N-th switch 328 of a power distribution network, in accordance with some embodiments. Block diagrams 300A and 300B include non-limiting examples of a power management controller selectively controlling electrical coupling or decoupling of various power net groups and a power distribution network. In some embodiments, switches 322, 324, and 328 correspond to switches 282, 284, 286, and/or 288 in FIG. 2B, or switches 292, 294, 296, and/or 298 in FIG. 2B. In some embodiments, power management controller 310 corresponds to power management controller 264 or power management controller 268 in FIG. 2B. In block diagrams 300A and 300B, three switches 322, 324, and 328 are depicted as a non-limiting example. In some embodiments, there are more or less than three switches in a power distribution network that are subject to control of a power management controller (e.g., N is a positive integer equal to or greater than 2).

In block diagrams 300A and 300B, each one of switches 322, 324, and 328 is based on a p-type transistor and has a first terminal (terminal 322a, 324a, or 328a) electrically coupled to a conductive path of a corresponding one of power net group 1, power net group 2, and power net group N. In block diagrams 300A and 300B, each one of switches 322, 324, and 328 has a second terminal (terminal 322b, 324b, or 328b) electrically coupled to a power node of a power distribution network (e.g., power distribution network 262 or 266 in FIG. 2A).

In FIG. 3A, block diagram 300A corresponds to switch 322 and switch 328 being turned off by power management controller 310; and switch 324 being turned on by power management controller 310. Based on the example of block diagram 300A, the power node of the power distribution network is energized by the supply voltage from power net group 2 through switch 324. In FIG. 3B, block diagram 300B corresponds to switches 322, 324, and 328 being turned on by power management controller 310. Based on the example of block diagram 300B, the power node of the power distribution network is energized by the supply voltages from power net group 1, power net group 2, and power net group N.

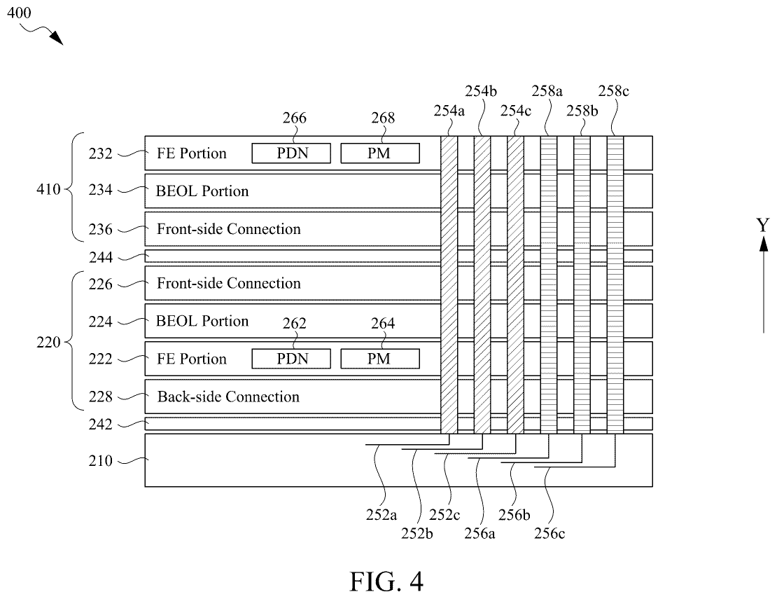

FIG. 4 is a simplified cross-sectional view of a second semiconductor device example 400, in accordance with some embodiments. In some embodiments, second semiconductor device example 400 is a variation based on first semiconductor device example 200 in FIGS. 2A-2B in view of the circuitry examples in FIGS. 3A-3B. As such, components in FIG. 4 that are the same or similar to those in FIGS. 2A-2B are given the same reference numbers, and description thereof is simplified or omitted.

In FIG. 4, second semiconductor device example 400 includes a substrate 210, a first semiconductor die 220 over substrate 210 along a stacking direction (e.g., the Y direction) and connected thereto through connections represented by block 242, and a second semiconductor die 410 over first semiconductor die 220 along the stacking direction and connected thereto through connections represented by block 244. In some embodiments, compared with second semiconductor die 230 of first semiconductor device example 200, second semiconductor die 410 of second semiconductor device example 400 does not include a back-side connection structure that corresponds to back-side connection 238. In FIG. 4 as a non-limiting example, first power distribution network 262 includes back-side power lines in the back-side connection 228 of first semiconductor die 220. In some other embodiments, since first semiconductor die 220 includes front-side and back-side connections, first semiconductor die 220 is disposed in an upside down position compared to the example in FIG. 4.

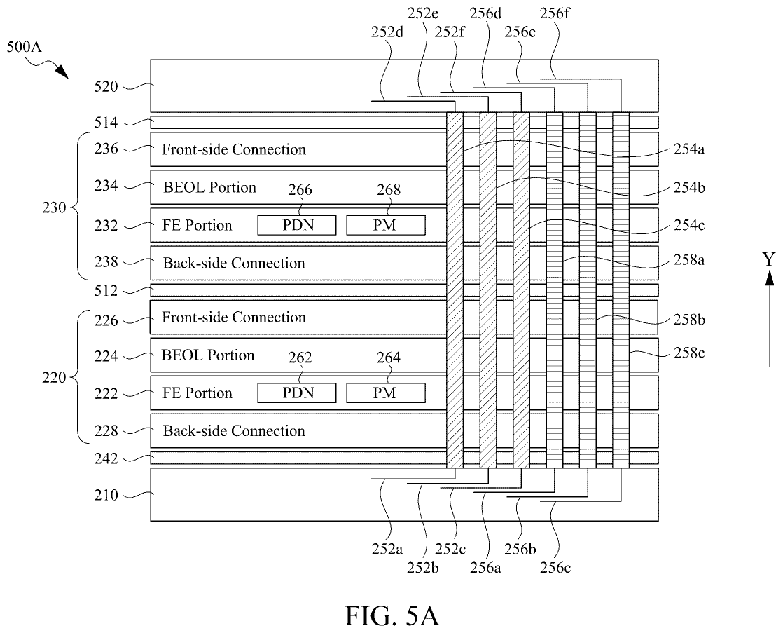

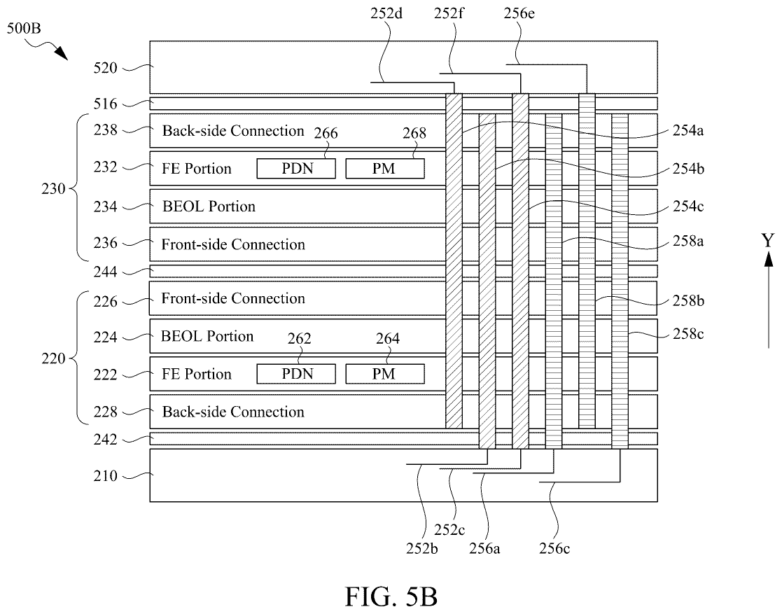

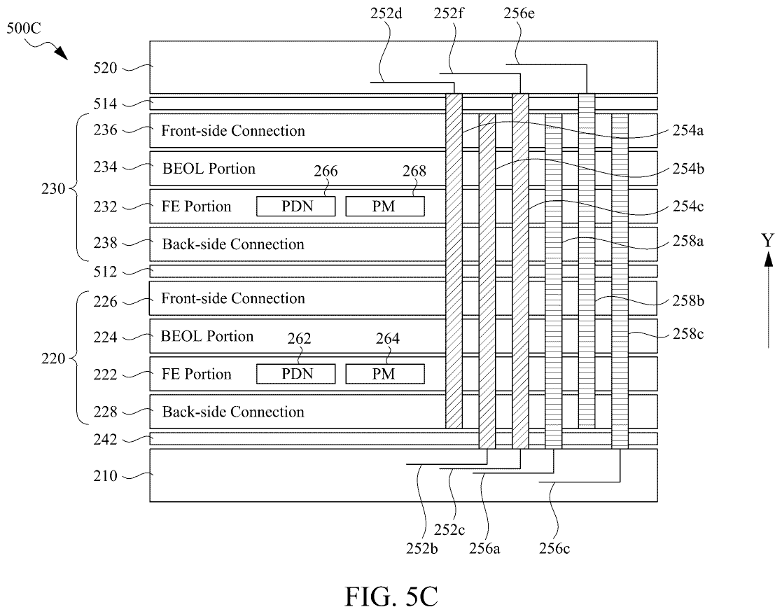

FIGS. 5A-5C are simplified cross-sectional views of a third semiconductor device example 500A, a fourth semiconductor device example 500B, and a fifth semiconductor device example 500C, in accordance with some embodiments. In some embodiments, third semiconductor device example 500A, fourth semiconductor device example 500B, and fifth semiconductor device example 500C are variations based on first semiconductor device example 200 in FIGS. 2A-2B in view of the circuitry examples in FIGS. 3A-3B. As such, components in FIGS. 5A-5C that are the same or similar to those in FIGS. 2A-2B are given the same reference numbers, and description thereof is simplified or omitted.

In FIG. 5A, third semiconductor device example 500A includes a substrate 210, a first semiconductor die 220 over substrate 210 along a stacking direction (e.g., the Y direction) and connected thereto through connections represented by block 242, a second semiconductor die 230 over first semiconductor die 220 along the stacking direction and connected thereto through connections represented by block 512, and another substrate 520 over second semiconductor die 230 along the stacking direction and connected thereto through connections represented by block 514. In this example, second semiconductor die 230 is disposed in an upside down position compared to the example in FIG. 2A.

In FIG. 5A, each one of the sets of conductive paths 254a, 254b, 254c, 258a, 258b, and 258c is electrically coupled to a corresponding power line (e.g., power lines 252a, 252b, 252c, 256a, 256b, and/or 256c) included in substrate 210, a corresponding power line (e.g., power lines 252d, 252e, 252f, 256d, 256e, and/or 256f) included in substrate 520, or both. In some embodiments, a subset of the power lines 252a, 252b, 252c, 256a, 256b, 256c, 252d, 252e, 252f, 256d, 256e, and 256f is omitted. In some embodiments, various non-limiting examples of how the the sets of conductive paths 254a, 254b, 254c, 258a, 258b, and 258c are electrically coupled to power lines included in substrate 210 and/or substrate 520 and the orientations of semiconductor dies are further illustrated in the examples in FIGS. 5B and 5C.

In FIG. 5B, fourth semiconductor device example 500B includes a substrate 210, a first semiconductor die 220 over substrate 210 along a stacking direction (e.g., the Y direction) and connected thereto through connections represented by block 242, a second semiconductor die 230 over first semiconductor die 220 along the stacking direction and connected thereto through connections represented by block 244, and another substrate 520 over second semiconductor die 230 along the stacking direction and connected thereto through connections represented by block 516. In FIG. 5B as a non-limiting example, the sets of conductive paths 254b, 254c, 258a, and 258c are electrically coupled to corresponding power lines 252b, 252c, 256a, and 256c included in substrate 210, and the sets of conductive paths 254a, 254c, and 258b are electrically coupled to corresponding power lines 252d, 252f, and 256e included in substrate 520.

In some embodiments, the power lines included in one of the substrates 210 and 520 are configured to carry positive supply voltages and/or a ground voltage, and the power lines included in the other one of the substrates 210 and 520 are configured to carry negative supply voltages and/or the ground voltage. In some embodiments, a portion of the power lines included in one of the substrates 210 and 520 are configured to carry supply voltages for circuit blocks with operation frequencies higher than a first threshold frequency (e.g., greater than 1 megahertz (MHz)), and a portion of the power lines included in the other one of the substrates 210 and 520 are configured to carry supply voltages for circuit blocks with operation frequencies lower than a second threshold frequency (e.g., less than 10 MHz).

In FIG. 5C, fifth semiconductor device example 500C includes a substrate 210, a first semiconductor die 220 over substrate 210 along a stacking direction (e.g., the Y direction) and connected thereto through connections represented by block 242, a second semiconductor die 230 over first semiconductor die 220 along the stacking direction and connected thereto through connections represented by block 512, and another substrate 520 over second semiconductor die 230 along the stacking direction and connected thereto through connections represented by block 514. In this example, second semiconductor die 230 is disposed in an upside down position compared to the example in FIG. 2A. In some embodiments, the orientation of first semiconductor die 220 and second semiconductor die 230 presented in FIGS. 5A-5C are merely non-limiting examples. In some other embodiments, first semiconductor die 220, second semiconductor die 230, or both, are disposed in an upside down position compared to any of the examples in FIGS. 5A-5C.

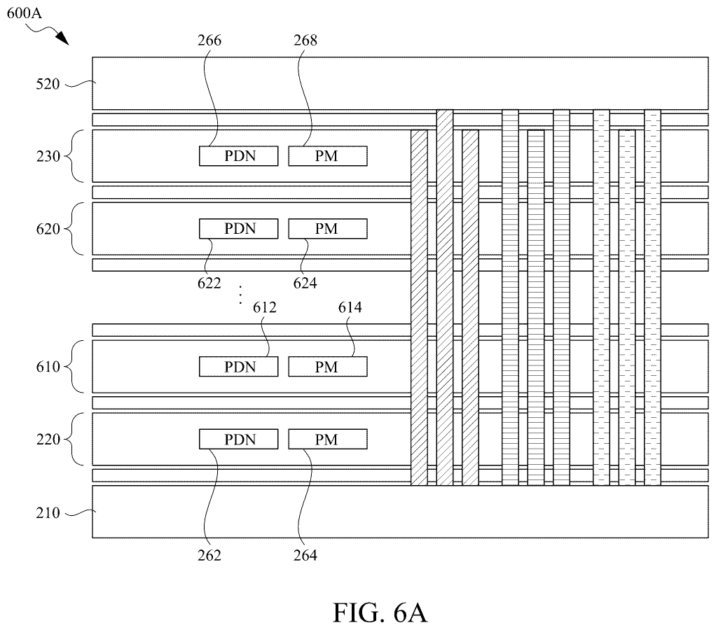

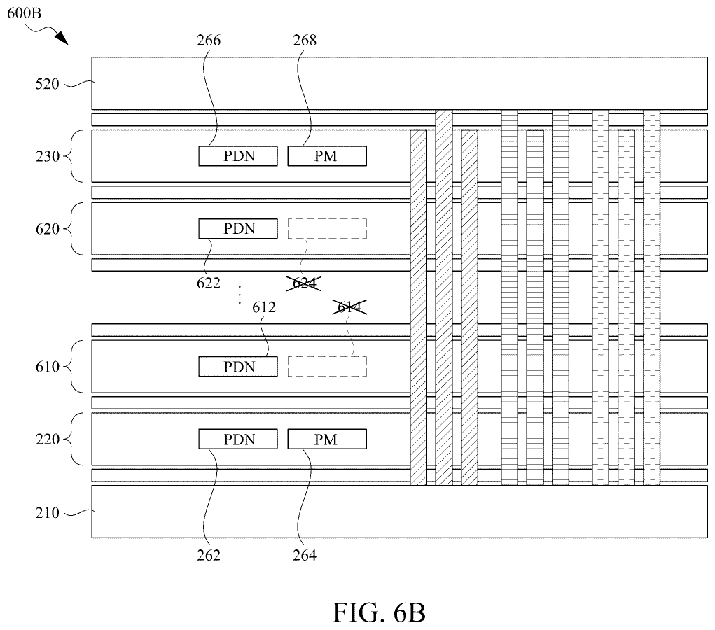

FIGS. 6A-6B are simplified cross-sectional views of a sixth semiconductor device example 600A and a seventh semiconductor device example 600B, in accordance with some embodiments. In some embodiments, sixth semiconductor device example 600A and seventh semiconductor device example 600B are variations based on third semiconductor device example 500A in FIG. 5A and first semiconductor device example 200 in FIGS. 2A-2B in view of the circuitry examples in FIGS. 3A-3B. As such, components in FIGS. 6A-6B that are the same or similar to those in FIGS. 2A-2B and 5 are given the same reference numbers, and description thereof is simplified or omitted. Also, for further clarity, some components are simplified, omitted, and/or not labeled in FIGS. 6A-6B compared to their counterparts in FIG. 5A.

In FIG. 6A, sixth semiconductor device example 600A includes a substrate 210, a first semiconductor die 220 over substrate 210, a second semiconductor die 230 over first semiconductor die 220, and another substrate 520 over second semiconductor die 230 along the stacking direction. Moreover, sixth semiconductor device example 600A further includes one or more semiconductor dies (e.g., semiconductor dies 610 and 620 in FIG. 6A) disposed between first semiconductor die 220 and second semiconductor die 230. That is, there are more than three semiconductor dies between substrate 210 and substrate 520. In some embodiments, each one of semiconductor dies 610 and 620 has a configuration including portions corresponding to a FE portion, a BEOL portion, a front-side connection structure, and a back-side connection structure, as illustrated in view of first semiconductor die 220 and second semiconductor die 230.

In some embodiments, semiconductor die 610 or semiconductor die 620 is over substrate 210 along the stacking direction and stacked with first semiconductor die 220 and second semiconductor die 230. In some embodiments, semiconductor dies 220, 230, 610, and 620 include corresponding power distribution networks 262, 266, 612, and 622 and corresponding power management controllers 264, 268, 614, and 624 for selectively coupling the power distribution networks to the various sets of conductive paths (not labeled). For example, each one of semiconductor die 610 or semiconductor die 620 includes a power distribution network (e.g., power distribution network 612 or power distribution network 622) and a conductive path corresponding to a part of a set of conductive paths, and a switch configured to electrically couple the power distribution network to the conductive path or electrically decouple the power distribution network from the conductive path of the corresponding semiconductor die. In some embodiments, the conductive path of the semiconductor die 610 or semiconductor die 620 is coupled to other conductive paths of first semiconductor die 220 and second semiconductor die 230 as part of various sets of conductive paths as illustrated above.

In FIG. 6B, seventh semiconductor device example 600B is a variation of sixth semiconductor device example 600A. Compared to sixth semiconductor device example 600A, some of the semiconductor dies (e.g., semiconductor die 610 and semiconductor die 620) in seventh semiconductor device example 600B do not include their own power management controllers (e.g., power management controller 614 and power management controller 624 with the cross marks). In some embodiments in such scenario, the corresponding power distribution network (e.g. power distribution network 612 or power distribution network 622) is hardwired to suitable sets of power net groups without the need for a power management controller. In some other embodiments in such scenario, the corresponding power distribution network (e.g. power distribution network 612 or power distribution network 622) is selectively coupled to suitable sets of power net groups by one or more other power management controllers in the semiconductor device 600B (e.g., power management controller 264 or power management controller 268).

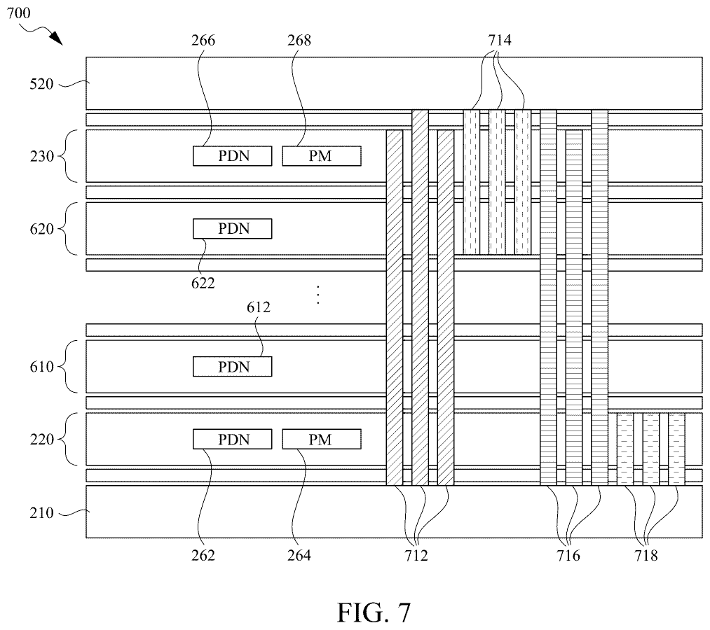

FIG. 7 is a simplified cross-sectional view of an eighth semiconductor device example 700, in accordance with some embodiments. In some embodiments, eighth semiconductor device example 700 is a variation based on seventh semiconductor device example 600B in FIG. 6B and first semiconductor device example 200 in FIGS. 2A-2B in view of the circuitry examples in FIGS. 3A-3B. As such, components in FIG. 7 that are the same or similar to those in FIGS. 2A-2B and 6B are given the same reference numbers, and description thereof is simplified or omitted.

In FIG. 7, eighth semiconductor device example 700 includes multiple sets of conductive paths 712, 714, 716, and 718 corresponding to four different power net groups. In some embodiments, a subset of the power net groups is configured for providing supply voltages to all semiconductor dies 220, 230, 610, and 620 of eighth semiconductor device example 700. In some embodiments, a subset of the power net groups is configured for providing supply voltages to a subset of semiconductor dies 220, 230, 610, and 620 of eighth semiconductor device example 700.

In FIG. 7 as a non-limiting example, the sets of conductive paths 712 correspond to a first power net group with two sets of conductive paths electrically coupled to corresponding power lines included in substrate 210 and one set of conductive paths electrically coupled to a corresponding power line included in substrate 520. In some embodiments, the sets of conductive paths 712 are configured for providing supply voltages to all semiconductor dies 220, 230, 610, and 620. In FIG. 7 as a non-limiting example, the sets of conductive paths 714 correspond to a second power net group with three sets of conductive paths electrically coupled to corresponding power lines included in substrate 520. In some embodiments, the sets of conductive paths 714 are configured for providing supply voltages to semiconductor dies 230 and 620. In FIG. 7 as a non-limiting example, the sets of conductive paths 716 correspond to a third power net group with two set of conductive paths electrically coupled to corresponding power lines included in substrate 520 and one set of conductive paths electrically coupled to a corresponding power line included in substrate 210. In some embodiments, the sets of conductive paths 716 are configured for providing supply voltages to all semiconductor dies 220, 230, 610, and 620. In FIG. 7 as a non-limiting example, the sets of conductive paths 718 correspond to a fourth power net group with three sets of conductive paths electrically coupled to corresponding power lines included in substrate 210. In some embodiments, the sets of conductive paths 718 are configured for providing supply voltages to semiconductor die 220.

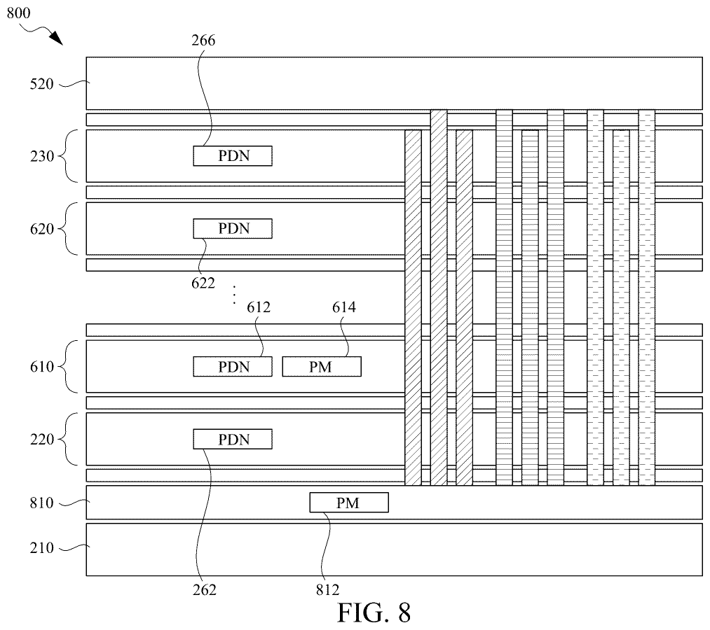

FIG. 8 is a simplified cross-sectional view of a ninth semiconductor device example 800, in accordance with some embodiments. In some embodiments, ninth semiconductor device example 800 is a variation based on seventh semiconductor device example 600B in FIG. 6B and first semiconductor device example 200 in FIGS. 2A-2B in view of the circuitry examples in FIGS. 3A-3B. As such, components in FIG. 8 that are the same or similar to those in FIGS. 2A-2B and 6B are given the same reference numbers, and description thereof is simplified or omitted.

In FIG. 8, ninth semiconductor device example 800 includes semiconductor dies 220, 610, 620, and 230 between substrates 210 and 520. In some embodiments, semiconductor dies 220, 610, 620, and 230 include corresponding power distribution networks 262, 612, 622, and 266. In this example, semiconductor die 610 further includes a power management controller 614, and semiconductor dies 220, 620, and 230 do not include power management controllers therein.

In FIG. 8, ninth semiconductor device example 800 further includes another semiconductor die 810 over substrate 210. In some embodiments, semiconductor die 810 includes a power management controller 812 that is configured to control various switches of power distribution networks 262, 266, and/or 622.

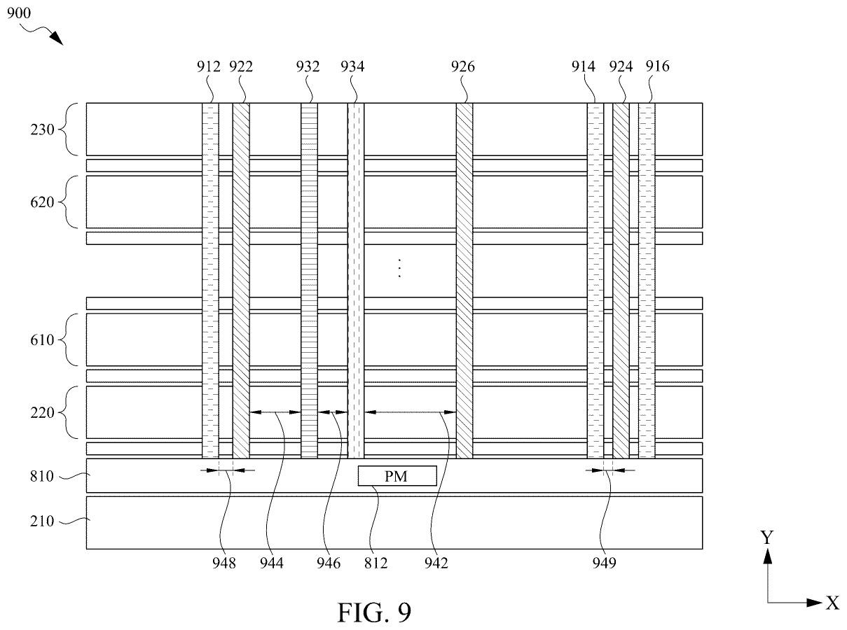

FIG. 9 is a simplified cross-sectional view of a tenth semiconductor device example 900, in accordance with some embodiments. In some embodiments, tenth semiconductor device example 900 is a variation based on ninth semiconductor device example 800 in FIG. 8 and first semiconductor device example 200 in FIGS. 2A-2B in view of the circuitry examples in FIGS. 3A-3B. As such, components in FIG. 9 that are the same or similar to those in FIGS. 2A-2B and 8 are given the same reference numbers, and description thereof is simplified or omitted. Also, compared to ninth semiconductor device example 800 in FIG. 8 and as a non-limiting example, tenth semiconductor device example 900 does not include another substrate (e.g., substrate 520) over the stack of semiconductor dies.

In FIG. 9, tenth semiconductor device example 900 includes multiple sets of conductive paths 912, 914, 916, 924, 922, 926, 932, and 934. In this non-limiting example, the sets of conductive paths 912, 914, and 916 are configured to carry a ground voltage or one or more supply voltages that are configured to energize one or more circuit blocks with a toggling rate less than ten times per second (e.g., ranging from 0 hertz (Hz) to 10 Hz, also referred to as an ultra low frequency range in this disclosure). In this non-limiting example, the sets of conductive paths 924, 924, and 926 are configured to carry one or more supply voltages that are configured to energize one or more circuit blocks with operation frequencies greater than a threshold ranging from 1 gigahertz (GHz) to 5 GHz, or even greater than 5 GHz (e.g., also referred to as a high frequency range in this disclosure). In this non-limiting example, the set of conductive paths 932 is configured to carry a supply voltage that is configured to energize one or more circuit blocks with operation frequencies ranging from 1 MHz to 1 GHz (e.g., also referred to as a medium frequency range in this disclosure). In this non-limiting example, the set of conductive paths 934 is configured to carry a supply voltage that is configured to energize one or more circuit blocks with operation frequencies ranging from 10 Hz to 1 MHz, or even lower than 10 Hz (e.g., also referred to as a low frequency range in this disclosure).

In some embodiments, each of the semiconductor dies 220, 230, 610, and 620 includes conductive structures extending along the stacking direction (e.g., the Y direction) and corresponding to various sets of conductive paths. In some embodiments, the sets of conductive paths 922 and 926 are configured to carry a supply voltage for energizing a circuitry having a first operation frequency at the high frequency range. In some embodiments, the set of conductive paths 932 is configured to carry a supply voltage for energizing a circuitry having a second operation frequency at the medium frequency range and less than the first operation frequency. In some embodiments, the set of conductive paths 934 is configured to carry a supply voltage for energizing a circuitry having a third operation frequency at the low frequency range and less than the second operation frequency. In some embodiments, a first distance (e.g., distance 942) in a planar direction (e.g., the X direction) perpendicular to the stacking direction between the sets of conductive paths 926 and 934 (e.g., the distance of the corresponding the conductive structure thereof) and a second distance (e.g., a combination of distances 942 and 946 or distance 944) in the planar direction between the sets of conductive paths 926 and 932 (or 922 and 932) are greater than a third distance in the planar direction between the sets of conductive paths 932 and 934 in order to avoid or mitigate noise coupling among the various sets of conductive paths.

In some embodiments, the conductive structures corresponding to the sets of conductive paths 922 and 924 (for powering circuitry of high frequency range) are disposed close to the conductive structures corresponding to the sets of conductive paths 912, 914, and 916 (for ground or powering circuitry of ultra low frequency range), such that the sets of conductive paths 912, 914, and 916 are configured to provide shielding for the sets of conductive paths 922 and 924. In some embodiments, a fourth distance (e.g., distance 948 or distance 949) in the planar direction between one of the sets of conductive paths 922 or 924 and the sets of conductive paths 912 or 914 adjacent thereto is less than the third distance 946.

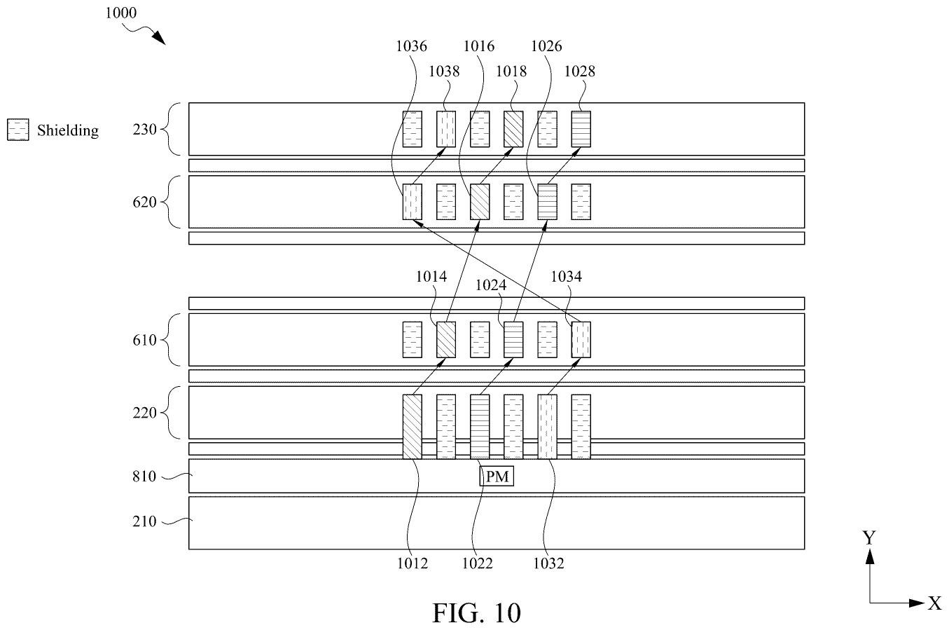

FIG. 10 is a simplified cross-sectional view of an eleventh semiconductor device example 1000, in accordance with some embodiments. In some embodiments, eleventh semiconductor device example 1000 is a variation based on ninth semiconductor device example 800 in FIG. 8 and first semiconductor device example 200 in FIGS. 2A-2B in view of the circuitry examples in FIGS. 3A-3B. As such, components in FIG. 10 that are the same or similar to those in FIGS. 2A-2B and 8 are given the same reference numbers, and description thereof is simplified or omitted. Also, compared to ninth semiconductor device example 800 in FIG. 8 and as a non-limiting example, eleventh semiconductor device example 1000 does not include another substrate (e.g., substrate 520) over the stack of semiconductor dies.

In FIG. 10, each semiconductor dies in eleventh semiconductor device example 1000 include conductive structures corresponding to various sets of conductive paths of one or more power net groups. In this example, a first set of conductive paths includes a conductive structure 1012 included in semiconductor die 220, a conductive structure 1014 included in semiconductor die 610, a conductive structure 1016 included in semiconductor die 620, and a conductive structure 1018 included in semiconductor die 230 electrically coupled together. A second set of conductive paths includes a conductive structure 1022 included in semiconductor die 220, a conductive structure 1024 included in semiconductor die 610, a conductive structure 1026 included in semiconductor die 620, and a conductive structure 1028 included in semiconductor die 230 electrically coupled together. Also, a third set of conductive paths includes a conductive structure 1032 included in semiconductor die 220, a conductive structure 1034 included in semiconductor die 610, a conductive structure 1036 included in semiconductor die 620, and a conductive structure 1038 included in semiconductor die 230 electrically coupled together. Moreover, other conductive structures in FIG. 10 indicated by legend “Shield” correspond to one or more other conductive paths configured to carry a ground voltage or a supply voltage usable for shielding.

In FIG. 10, the conductive structures of a same set of conductive paths in adjacent semiconductor dies are shifted with respect to each other in a planar direction (e.g., X direction) perpendicular to the stacking direction (e.g., Y direction). For example, conductive structure 1012 and conductive structure 1014 are electrically coupled to each other, but are misaligned along the stacking direction. In some embodiments, the conductive structures of a same set of conductive paths form a helix power connection through various semiconductor dies of eleventh semiconductor device example 1000. Accordingly, the sets of conductive paths are spatially intertwined to reduce the variations of noise levels thereon.

In view of the examples in FIGS. 2-10, in some embodiments, a semiconductor device includes a first substrate (e.g., substrate 210 in FIG. 2A) including a first power line (e.g., power line 252c), a first semiconductor die (e.g., semiconductor die 220 in FIG. 2A) over the first substrate along a stacking direction, and a second semiconductor die (e.g., semiconductor die 230 in FIG. 2A) over the first semiconductor die along the stacking direction. In some embodiments, the first semiconductor die includes a first power distribution network (e.g., power distribution network 262), a first conductive path (e.g., conductive path 272c in FIG. 2B), and a first switch (e.g., switch 284 in FIG. 2B) configured to electrically couple the first power distribution network to the first conductive path or electrically decouple the first power distribution network from the first conductive path. In some embodiments, the second semiconductor die including a second power distribution network (e.g., power distribution network 266), a second conductive path (e.g., conductive path 274c in FIG. 2B), and a second switch (e.g., switch 294 in FIG. 2B) configured to electrically couple the second power distribution network to the second conductive path or electrically decouple the second power distribution network from the second conductive path. In some embodiments, the semiconductor device further includes one or more power management controllers (e.g., power management controllers 264 and 268) configured to control the first switch, the second switch, or both.

In some embodiments, the first conductive path and the second conductive path are electrically coupled to each other, electrically coupled to the first power line, and are configured to carry a first supply voltage. In some embodiments, the one or more power management controllers are individually or collectively included in the first semiconductor die, included in the second semiconductor die, or included in a third semiconductor die different from the first semiconductor die and the second semiconductor die.

In some embodiments, the first semiconductor die further includes a third conductive path (e.g., conductive path 276c in FIG. 2B), and a third switch (e.g., switch 288) configured to electrically couple the first power distribution network to the third conductive path or electrically decouple the first power distribution network from the third conductive path. In some embodiments, the second semiconductor die further includes a fourth conductive path (e.g., conductive path 278c in FIG. 2B), and a fourth switch (e.g., switch 296) configured to electrically couple the second power distribution network to the fourth conductive path or electrically decouple the second power distribution network from the fourth conductive path. In some embodiments, the one or more power management controllers are configured to control the third switch, the fourth switch, or both. In some embodiments, the third conductive path and the fourth conductive path are electrically coupled to each other and are configured to carry a second supply voltage. In some embodiments, the first switch and the third switch are electrically coupled to a same power node of the first power distribution network. In some embodiments, the first switch and the third switch are electrically coupled to different power nodes of the first power distribution network.

In some embodiments, the semiconductor device further includes a second substrate (e.g., substrate 520 in FIG. 5A) over the second semiconductor die along the stacking direction and including a second power line (e.g., power lines 256f). in some embodiments, the third conductive path and the fourth conductive path are electrically coupled to each other, and electrically coupled to the second power line.

In some embodiments, the first substrate includes a third power line, and the third conductive path and the fourth conductive path are electrically coupled to each other, and electrically coupled to the third power line. In some embodiments, the first power line is configured in association with a first power net group of the semiconductor device, and the third power line is configured in association with a second power net group of the semiconductor device.

In some embodiments, the one or more power management controllers include one or both of a first power management controller included in the first semiconductor die, or a second power management controller included in the second semiconductor die. In some embodiments, the one or more power management controllers include a third power management controller included in the third semiconductor die, and the third semiconductor die is between the first substrate and the first semiconductor die.

In some embodiments, the semiconductor device further includes a third semiconductor die (e.g., semiconductor die 610 or 520) over the first substrate along the stacking direction and stacked with the first semiconductor die and the second semiconductor die. In some embodiments, the third semiconductor die includes a third power distribution network, a fifth conductive path, and a fifth switch configured to electrically couple the third power distribution network to the fifth conductive path or electrically decouple the third power distribution network from the fifth conductive path. In some embodiments, the fifth conductive path is electrically coupled to the first conductive path and the second conductive path, or the fifth conductive path is electrically separated from the first conductive path and the second conductive path.

In some embodiments, the first conductive path and the second conductive path are misaligned along the stacking direction. In some embodiments, the first semiconductor die further includes a fifth conductive path configured to carry a third supply voltage and a sixth conductive path configured to carry a fourth supply voltage. In some embodiments, the first supply voltage is configured to energize a first circuitry having a first operation frequency, the third supply voltage is configured to energize a second circuitry having a second operation frequency less than the first operation frequency, and the fourth supply voltage is configured to energize a third circuitry having a third operation frequency less than the second operation frequency. In some embodiments, a first distance in a planar direction perpendicular to the stacking direction between the first conductive path and the fifth conductive path and a second distance in the planar direction between the first conductive path and the sixth conductive path are greater than a third distance in the planar direction between the fifth conductive path and the sixth conductive path.

In some embodiments, the first semiconductor die further includes a seventh conductive path configured to carry a fifth supply voltage. In some embodiments, the fifth supply voltage is configured to energize a fourth circuitry having a toggling rate less than 10 times per second or corresponds to a ground of the semiconductor device, and a fourth distance in the planar direction between the first conductive path and the seventh conductive path is less than the third distance between the fifth conductive path and the sixth conductive path.

In view of the examples in FIGS. 2-10, in some embodiments, a semiconductor device includes a first semiconductor die (e.g., semiconductor die 220 in FIG. 2A) including a first power distribution network (e.g., power distribution network 262 in FIG. 2A) and a second semiconductor die (e.g., semiconductor die 230 in FIG. 2A) over the first semiconductor die and including a second power distribution network (e.g., power distribution network 266 in FIG. 2A). in some embodiments, the semiconductor device further includes a first set of conductive paths (e.g., the set of conductive paths 254a in FIG. 2A) through the first semiconductor die and the second semiconductor die and associated with a first power net group of the semiconductor device, and a second set of conductive paths (e.g., the set of conductive paths 258a in FIG. 2A) through the first semiconductor die and the second semiconductor die and associated with a second power net group of the semiconductor device. In some embodiments, the semiconductor device further includes one or more power management controllers (e.g., power management controller 264 and/or power management controller 268) configured to set the first power distribution network as electrically coupled to the first set of conductive paths, the second set of conductive paths, or both; or set the second power distribution network as electrically coupled to the first set of conductive paths, the second set of conductive paths, or both.

In some embodiments, the semiconductor device further includes a first substrate (e.g., substrate 210 in FIG. 2A), where the first semiconductor die is over the first substrate. In some embodiments, the first set of conductive paths is electrically coupled to a first power line (e.g., power line 252a) included in the first substrate. In some embodiments, the semiconductor device further includes a second substrate (e.g., substrate 520 in FIG. 5A) over the second semiconductor die. In some embodiments, the second set of conductive paths is electrically coupled to a second power line (e.g., power line 256d) included in the second substrate.

In some embodiments, the first power net group includes a first plurality of power nets configured to carry first supply voltages. In some embodiments, the second power net group includes a second plurality of power nets configured to carry second supply voltages. In some embodiments, the one or more power management controllers comprise one or both of a first power management controller included in the first semiconductor die, or a second power management controller included in the second semiconductor die.

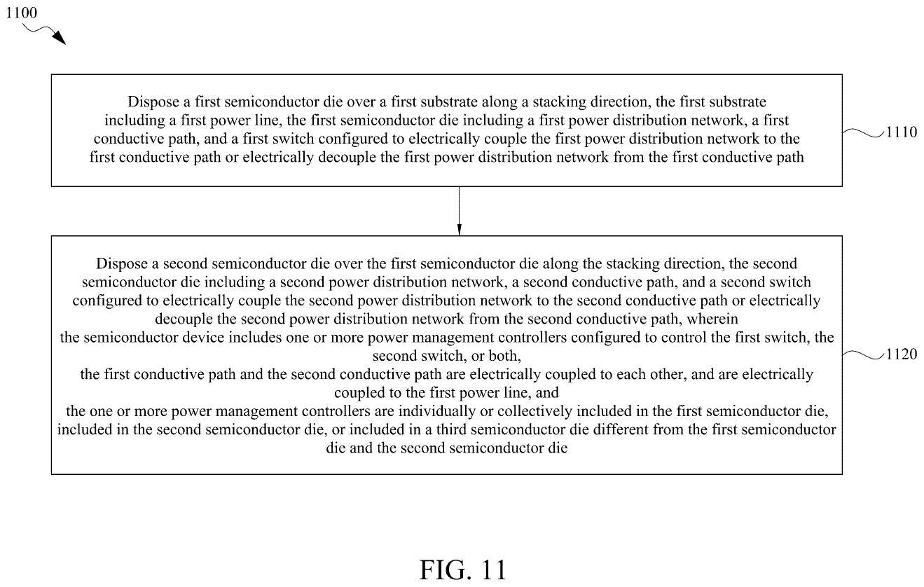

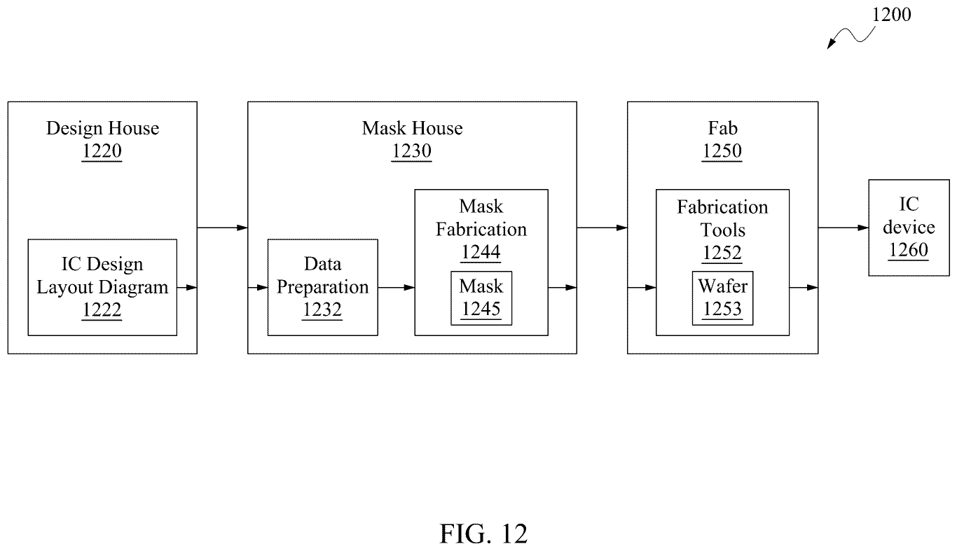

FIG. 11 is a flowchart of a method 1100 of manufacturing a semiconductor device, in accordance with some embodiments. In some embodiments, various operations of method 1100 correspond to manufacturing a semiconductor device based on various combinations of the examples in FIGS. 2A-10. In some embodiments, method 1100 corresponds to one or more operations performed based on, in whole or in part, an integrated circuit (IC) manufacturing system 1200 as illustrated in FIG. 12. As in FIG. 11, method 1100 includes blocks 1110-1120.

At block 1110, a first semiconductor die (e.g., semiconductor die 220 in FIG. 2A) is disposed over a first substrate (e.g., substrate 210 in FIG. 2A) along a stacking direction, the first substrate including a first power line (e.g., power line 252c). In some embodiments, the first semiconductor die includes a first power distribution network (e.g., power distribution network 262), a first conductive path (e.g., conductive path 272c in FIG. 2B), and a first switch (e.g., switch 284 in FIG. 2B) configured to electrically couple the first power distribution network to the first conductive path or electrically decouple the first power distribution network from the first conductive path.

At block 1120, a second semiconductor die (e.g., semiconductor die 230 in FIG. 2A) is disposed over the first semiconductor die along the stacking direction. In some embodiments, the second semiconductor die including a second power distribution network (e.g., power distribution network 266), a second conductive path (e.g., conductive path 274c in FIG. 2B), and a second switch (e.g., switch 294 in FIG. 2B) configured to electrically couple the second power distribution network to the second conductive path or electrically decouple the second power distribution network from the second conductive path.

In some embodiments, the semiconductor device includes one or more power management controllers (e.g., power management controllers 264 and 268) configured to control the first switch, the second switch, or both. In some embodiments, the first conductive path and the second conductive path are electrically coupled to each other, and are electrically coupled to the first power line. In some embodiments, the one or more power management controllers are individually or collectively included in the first semiconductor die (e.g., power management controller 264 in semiconductor die 210 in FIG. 2A), included in the second semiconductor die (e.g., power management controller 268 in semiconductor die 220 in FIG. 2A), or included in a third semiconductor die (e.g., power management controller 812 in semiconductor die 810 in FIG. 8) different from the first semiconductor die and the second semiconductor die.

In some embodiments, method 1100 further includes disposing a second substrate (e.g., substrate 520 in FIG. 5A) over the second semiconductor die along the stacking direction and including a second power line (e.g., power lines 256f). In some embodiments, the first semiconductor die further includes a third conductive path (e.g., conductive path 276c in FIG. 2B), and a third switch (e.g., switch 288) configured to electrically couple the first power distribution network to the third conductive path or electrically decouple the first power distribution network from the third conductive path. In some embodiments, the second semiconductor die further includes a fourth conductive path (e.g., conductive path 278c in FIG. 2B), and a fourth switch (e.g., switch 296) configured to electrically couple the second power distribution network to the fourth conductive path or electrically decouple the second power distribution network from the fourth conductive path. In some embodiments, the one or more power management controllers are configured to control the third switch, the fourth switch, or both. In some embodiments, the third conductive path structure and the fourth conductive path structure are electrically coupled to each other, and electrically coupled to the second power line.

In some embodiments, the method 1100 further includes disposing a third semiconductor die (e.g., semiconductor die 610 or semiconductor die 620 in FIG. 6A) between the first substrate and the first semiconductor die. In some embodiments, the one or more power management controllers corresponds to a power management controller (e.g., power management controller 614 and/or power management controller 624) included in the third semiconductor die.

FIG. 12 is a block diagram of an integrated circuit (IC) manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1200.

In FIG. 12, IC manufacturing system 1200 includes entities, such as a design house 1220, a mask house 1230, and an IC manufacturer/fabricator (fab) 1250, that interact with one another in the design, development, and manufacturing cycles and/or services related to manufacturing an IC device 1260. The entities in system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1220, mask house 1230, and IC fab 1250 is owned by a single larger company. In some embodiments, two or more of design house 1220, mask house 1230, and IC fab 1250 coexist in a common facility and use common resources.

Design house (or design team) 1220 generates an IC design layout diagram 1222. IC design layout diagram 1222 includes various geometrical patterns designed for an IC device 1260. The geometrical patterns correspond to patterns of metal, oxide, or semiconductor layers that make up the various components of IC device 1260 to be fabricated. The various layers combine to form various IC features. For example, a portion of IC design layout diagram 1222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1220 implements a proper design procedure to form IC design layout diagram 1222. The design procedure includes one or more of logic design, physical design or place and route. IC design layout diagram 1222 is presented in one or more data files having information of the geometrical patterns. For example, IC design layout diagram 1222 can be expressed in a GDSII file format or DFII file format.

Mask house 1230 includes data preparation 1232 and mask fabrication 1244. Mask house 1230 uses IC design layout diagram 1222 to manufacture one or more masks 1245 to be used for fabricating the various layers of IC device 1260 according to IC design layout diagram 1222. Mask house 1230 performs mask data preparation 1232, where IC design layout diagram 1222 is translated into a representative data file (RDF). Mask data preparation 1232 provides the RDF to mask fabrication 1244. Mask fabrication 1244 includes a mask writer. A mask writer converts the RDF to an image on a substrate, such as a mask (reticle) 1245 or a semiconductor wafer 1253. The design layout diagram 1222 is manipulated by mask data preparation 1232 to comply with particular characteristics of the mask writer and/or requirements of IC fab 1250. In FIG. 12, mask data preparation 1232 and mask fabrication 1244 are illustrated as separate elements. In some embodiments, mask data preparation 1232 and mask fabrication 1244 can be collectively referred to as mask data preparation.

In some embodiments, mask data preparation 1232 includes optical proximity correction (OPC) which uses lithography enhancement techniques to compensate for image errors, such as those that can arise from diffraction, interference, other process effects and the like. OPC adjusts IC design layout diagram 1222. In some embodiments, mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1232 includes a mask rule checker (MRC) that checks the IC design layout diagram 1222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1222 to compensate for photolithographic implementation effects during mask fabrication 1244, which may undo part of the modifications performed by OPC in order to meet mask creation rules.

In some embodiments, mask data preparation 1232 includes lithography process checking (LPC) that simulates processing that will be implemented by IC fab 1250 to fabricate IC device 1260. LPC simulates this processing based on IC design layout diagram 1222 to create a simulated manufactured device, such as IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1222.

It should be understood that the above description of mask data preparation 1232 has been simplified for the purposes of clarity. In some embodiments, data preparation 1232 includes additional features such as a logic operation (LOP) to modify the IC design layout diagram 1222 according to manufacturing rules. Additionally, the processes applied to IC design layout diagram 1222 during data preparation 1232 may be executed in a variety of different orders.

After mask data preparation 1232 and during mask fabrication 1244, a mask 1245 or a group of masks 1245 are fabricated based on the modified IC design layout diagram 1222. In some embodiments, mask fabrication 1244 includes performing one or more lithographic exposures based on IC design layout diagram 1222. In some embodiments, an electron-beam (e-beam) or a mechanism of multiple e-beams is used to form a pattern on a mask (photomask or reticle) 1245 based on the modified IC design layout diagram 1222. Mask 1245 can be formed in various technologies. In some embodiments, mask 1245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1245 includes a transparent substrate (e.g., fused quartz) and an opaque material (e.g., chromium) coated in the opaque regions of the binary mask. In another example, mask 1245 is formed using a phase shift technology. In a phase shift mask (PSM) version of mask 1245, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1244 is used in a variety of processes. For example, such a mask(s) is used in an ion implantation process to form various doped regions in semiconductor wafer 1253, in an etching process to form various etching regions in semiconductor wafer 1253, and/or in other suitable processes.

IC fab 1250 is an IC fabrication business that includes one or more manufacturing facilities for the fabrication of a variety of different IC products. In some embodiments, IC Fab 1250 is a semiconductor foundry. For example, there may be a manufacturing facility for the front end fabrication of a plurality of IC products (FEOL fabrication), while a second manufacturing facility may provide the back end fabrication for the interconnection and packaging of the IC products (BEOL fabrication), and a third manufacturing facility may provide other services for the foundry business.

IC fab 1250 includes fabrication tools 1252 configured to execute various manufacturing operations on semiconductor wafer 1253 such that IC device 1260 is fabricated in accordance with the mask(s), e.g., mask 1245. In various embodiments, fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1250 uses mask(s) 1245 fabricated by mask house 1230 to fabricate IC device 1260. Thus, IC fab 1250 at least indirectly uses IC design layout diagram 1222 to fabricate IC device 1260. In some embodiments, semiconductor wafer 1253 is fabricated by IC fab 1250 using mask(s) 1245 to form IC device 1260. In some embodiments, the IC fabrication includes performing one or more lithographic exposures based at least indirectly on IC design layout diagram 1222. Semiconductor wafer 1253 includes a silicon substrate or other proper substrate having material layers formed thereon. Semiconductor wafer 1253 further includes one or more of various doped regions, dielectric features, multilevel interconnects, and the like (formed at subsequent manufacturing steps). In some embodiments, semiconductor wafer 1253 is further dissected into semiconductor dies. In some embodiments, IC device 1260 is based on or more semiconductor dies. In some embodiments, IC fab 1250 includes advanced packaging processes to form IC device 1260 based on packaging one or more semiconductor dies in an IC package.

In some aspects, a semiconductor device includes a first substrate including a first power line and a first semiconductor die over the first substrate along a stacking direction. The first semiconductor die includes a first power distribution network, a first conductive path, and a first switch configured to electrically couple the first power distribution network to the first conductive path or electrically decouple the first power distribution network from the first conductive path. The semiconductor device includes a second semiconductor die over the first semiconductor die along the stacking direction. The second semiconductor die includes a second power distribution network, a second conductive path, and a second switch configured to electrically couple the second power distribution network to the second conductive path or electrically decouple the second power distribution network from the second conductive path. The semiconductor device further includes one or more power management controllers configured to control the first switch, the second switch, or both. The first conductive path and the second conductive path are electrically coupled to each other, electrically coupled to the first power line, and are configured to carry a first supply voltage. The one or more power management controllers are individually or collectively included in the first semiconductor die, included in the second semiconductor die, or included in a third semiconductor die different from the first semiconductor die and the second semiconductor die.

In some aspects, a semiconductor device includes a first semiconductor die including a first power distribution network, a second semiconductor die over the first semiconductor die and including a second power distribution network, a first set of conductive paths through the first semiconductor die and the second semiconductor die and associated with a first power net group of the semiconductor device, and a second set of conductive paths through the first semiconductor die and the second semiconductor die and associated with a second power net group of the semiconductor device. The semiconductor device further includes one or more power management controllers configured to set the first power distribution network as electrically coupled to the first set of conductive paths, the second set of conductive paths, or both; or to set the second power distribution network as electrically coupled to the first set of conductive paths, the second set of conductive paths, or both.

In some aspects, a method of manufacturing a semiconductor device includes disposing a first semiconductor die over a first substrate along a stacking direction, the first substrate including a first power line, the first semiconductor die including a first power distribution network, a first conductive path, and a first switch configured to electrically couple the first power distribution network to the first conductive path or electrically decouple the first power distribution network from the first conductive path. The method of manufacturing the semiconductor device further includes disposing a second semiconductor die over the first semiconductor die along the stacking direction, the second semiconductor die including a second power distribution network, a second conductive path, and a second switch configured to electrically couple the second power distribution network to the second conductive path or electrically decouple the second power distribution network from the second conductive path. The semiconductor device includes one or more power management controllers configured to control the first switch, the second switch, or both. The first conductive path and the second conductive path are electrically coupled to each other, and are electrically coupled to the first power line. The one or more power management controllers are individually or collectively included in the first semiconductor die, included in the second semiconductor die, or included in a third semiconductor die different from the first semiconductor die and the second semiconductor die.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A semiconductor device, comprising:
a first substrate including a first power line;
a first semiconductor die over the first substrate along a stacking direction, the first semiconductor die including a first power distribution network, a first conductive path, and a first switch configured to electrically couple the first power distribution network to the first conductive path or electrically decouple the first power distribution network from the first conductive path;
a second semiconductor die over the first semiconductor die along the stacking direction, the second semiconductor die including a second power distribution network, a second conductive path, and a second switch configured to electrically couple the second power distribution network to the second conductive path or electrically decouple the second power distribution network from the second conductive path; and
one or more power management controllers configured to control the first switch, the second switch, or both,
wherein
the first conductive path and the second conductive path are electrically coupled to each other, electrically coupled to the first power line, and are configured to carry a first supply voltage, and
the one or more power management controllers are individually or collectively included in the first semiconductor die, included in the second semiconductor die, or included in a third semiconductor die different from the first semiconductor die and the second semiconductor die.

2. The semiconductor device of claim 1, wherein
the first semiconductor die further includes a third conductive path, and a third switch configured to electrically couple the first power distribution network to the third conductive path or electrically decouple the first power distribution network from the third conductive path,
the second semiconductor die further includes a fourth conductive path, and a fourth switch configured to electrically couple the second power distribution network to the fourth conductive path or electrically decouple the second power distribution network from the fourth conductive path,
the one or more power management controllers are configured to control the third switch, the fourth switch, or both, and
the third conductive path and the fourth conductive path are electrically coupled to each other and are configured to carry a second supply voltage.

3. The semiconductor device of claim 2, wherein
the first switch and the third switch are electrically coupled to a same power node of the first power distribution network, or
the first switch and the third switch are electrically coupled to different power nodes of the first power distribution network.

4. The semiconductor device of claim 2, further comprising:
a second substrate over the second semiconductor die along the stacking direction and including a second power line,
wherein the third conductive path and the fourth conductive path are electrically coupled to each other, and electrically coupled to the second power line.

5. The semiconductor device of claim 2, wherein
the first substrate includes a third power line, and
the third conductive path and the fourth conductive path are electrically coupled to each other, and electrically coupled to the third power line.

6. The semiconductor device of claim 5, wherein
the first power line is configured in association with a first power net group of the semiconductor device, and
the third power line is configured in association with a second power net group of the semiconductor device.

7. The semiconductor device of claim 1, wherein the one or more power management controllers comprise one or both of:
a first power management controller included in the first semiconductor die; or
a second power management controller included in the second semiconductor die.

8. The semiconductor device of claim 1, wherein
the one or more power management controllers comprise a third power management controller included in the third semiconductor die, and
the third semiconductor die is between the first substrate and the first semiconductor die.

9. The semiconductor device of claim 1, further comprising:
a third semiconductor die over the first substrate along the stacking direction and stacked with the first semiconductor die and the second semiconductor die, the third semiconductor die including a third power distribution network, a fifth conductive path, and a fifth switch configured to electrically couple the third power distribution network to the fifth conductive path or electrically decouple the third power distribution network from the fifth conductive path,
wherein
the fifth conductive path is electrically coupled to the first conductive path and the second conductive path, or
the fifth conductive path is electrically separated from the first conductive path and the second conductive path.

10. The semiconductor device of claim 1, wherein
the first conductive path and the second conductive path are misaligned along the stacking direction.

11. The semiconductor device of claim 1, wherein
the first semiconductor die further includes a fifth conductive path configured to carry a third supply voltage and a sixth conductive path configured to carry a fourth supply voltage,
the first supply voltage is configured to energize a first circuitry having a first operation frequency,
the third supply voltage is configured to energize a second circuitry having a second operation frequency less than the first operation frequency,
the fourth supply voltage is configured to energize a third circuitry having a third operation frequency less than the second operation frequency, and
a first distance in a planar direction perpendicular to the stacking direction between the first conductive path and the fifth conductive path and a second distance in the planar direction between the first conductive path and the sixth conductive path are greater than a third distance in the planar direction between the fifth conductive path and the sixth conductive path.

12. The semiconductor device of claim 11, wherein
the first semiconductor die further includes a seventh conductive path configured to carry a fifth supply voltage,
the fifth supply voltage is configured to energize a fourth circuitry having a toggling rate less than 10 times per second or corresponds to a ground of the semiconductor device, and
a fourth distance in the planar direction between the first conductive path and the seventh conductive path is less than the third distance between the fifth conductive path and the sixth conductive path.

13. A semiconductor device, comprising:
a first semiconductor die including a first power distribution network;
a second semiconductor die over the first semiconductor die and including a second power distribution network;
a first set of conductive paths through the first semiconductor die and the second semiconductor die and associated with a first power net group of the semiconductor device;
a second set of conductive paths through the first semiconductor die and the second semiconductor die and associated with a second power net group of the semiconductor device; and
one or more power management controllers configured to:
set the first power distribution network as electrically coupled to the first set of conductive paths, the second set of conductive paths, or both, or
set the second power distribution network as electrically coupled to the first set of conductive paths, the second set of conductive paths, or both.

14. The semiconductor device of claim 13, further comprising:
a first substrate, the first semiconductor die being over the first substrate,
wherein the first set of conductive paths is electrically coupled to a first power line included in the first substrate.

15. The semiconductor device of claim 14, further comprising:
a second substrate over the second semiconductor die,
wherein the second set of conductive paths is electrically coupled to a second power line included in the second substrate.

16. The semiconductor device of claim 13, wherein
the first power net group includes a first plurality of power nets configured to carry first supply voltages, and
the second power net group includes a second plurality of power nets configured to carry second supply voltages.

17. The semiconductor device of claim 13, wherein the one or more power management controllers comprise one or both of:
a first power management controller included in the first semiconductor die; or
a second power management controller included in the second semiconductor die.

18. A method of manufacturing a semiconductor device, comprising:
disposing a first semiconductor die over a first substrate along a stacking direction, the first substrate including a first power line, the first semiconductor die including a first power distribution network, a first conductive path, and a first switch configured to electrically couple the first power distribution network to the first conductive path or electrically decouple the first power distribution network from the first conductive path; and
disposing a second semiconductor die over the first semiconductor die along the stacking direction, the second semiconductor die including a second power distribution network, a second conductive path, and a second switch configured to electrically couple the second power distribution network to the second conductive path or electrically decouple the second power distribution network from the second conductive path,
wherein
the semiconductor device includes one or more power management controllers configured to control the first switch, the second switch, or both,
the first conductive path and the second conductive path are electrically coupled to each other, and are electrically coupled to the first power line, and
the one or more power management controllers are individually or collectively included in the first semiconductor die, included in the second semiconductor die, or included in a third semiconductor die different from the first semiconductor die and the second semiconductor die.

19. The method of claim 18, further comprising:
disposing a second substrate over the second semiconductor die along the stacking direction, the second substrate including a second power line,
wherein
the first semiconductor die further includes a third conductive path, and a third switch configured to electrically couple the first power distribution network to the third conductive path or electrically decouple the first power distribution network from the third conductive path,
the second semiconductor die further includes a fourth conductive path, and a fourth switch configured to electrically couple the second power distribution network to the fourth conductive path or electrically decouple the second power distribution network from the fourth conductive path,
the one or more power management controllers are configured to control the third switch, the fourth switch, or both, and
the third conductive path and the fourth conductive path are electrically coupled to each other, and electrically coupled to the second power line.

20. The method of claim 18, further comprising:
disposing a third semiconductor die between the first substrate and the first semiconductor die,
wherein the one or more power management controllers corresponds to a power management controller included in the third semiconductor die.
